(19) United States
(12) Patent Application Publication
(10) Pub. No.: US 2008/0087318 A1
(43) Pub. Date: Apr. 17, 2008

(54) Solar tracking device

(76) Inventor: Hwu Yi Jwo, Tainan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/802,271

(22) Filed: May 22, 2007

(30) Foreign Application Priority Data
Oct. 16, 2006 (TW) 095218321

(51) Int. Cl. H01L 31/042

(52) U.S. Cl. 136/244

(57) ABSTRACT

An improved elastic compression type solar tracking device includes a photoelectric plate or solar energy collecting device supported by an elastic element. A compression status of the elastic element can be changed by filling water into a water tank mounted on the photoelectric plate or solar energy collecting device to adjust the angle between the photoelectric plate or solar energy collecting device and a horizontal plane for maximum solar energy absorbing effect. The elastic compression type solar tracking device can be mounted on both sloping roofs and flat roofs of buildings.

### BACKGROUND OF THE INVENTION

1. Field of the Invention

The present invention relates to a solar tracking device and, more particularly, to an elastic compression type solar tracking device.

2. Description of the Related Art

Currently available photoelectric plates or solar energy collecting devices are fixed and, thus, have unsatisfactory effect. Taiwan Utility Model No. M284856 discloses a spring type solar tracking device that allows the photoelectric plates or solar energy collecting devices to be in a better angle facing the sun for obtaining a better effect in absorption of solar energy. As a result, the solar tracking device can allow the photoelectric plates or solar energy collecting devices to face the sun at any time and, thus, greatly enhance the solar energy absorbing efficiency at low costs while consuming less energy. Specifically, one or more photoelectric plates or solar energy collecting devices are utilized to absorb solar energy, with springs provided in the east and the west, and with one or more water tanks provided in the east, wherein water can be filled into the water tanks to provide the photoelectric plates or solar energy collecting devices with a tendency to turn toward the east. One or more rotational shafts are provided to allow the photoelectric plates or solar energy collecting devices to turn toward the east or the west. However, the solar tracking device can only be used on a flat surface; namely, the solar tracking device cannot be used on a sloping roof of a building that is common in oriental and western architecture for presenting aesthetically pleasing outlines. As a result, application of such a solar tracking device is limited.

### SUMMARY OF THE INVENTION

In view of the above problems, the present invention is intended to provide a solar tracking device that can be used on both sloping roofs and flat roofs of buildings. An elastic compression type solar tracking device according to the preferred teachings of the present invention includes a photoelectric plate or solar energy collecting device; an elastic element abutting against and supporting an irradiated side of the photoelectric plate or solar energy collecting device at a first supporting point; a rotational shaft connected to and supporting the photoelectric plate or solar energy collecting device at a second supporting point between the first supporting point and an end edge of the photoelectric plate or solar energy collecting device; a post for supporting the rotational shaft; a water tank mounted on the photoelectric plate or solar energy collecting device in a location other than the second supporting point where the rotational shaft supports the photoelectric plate or solar energy collecting device, with the water tank including a water filling control valve and a water discharge control valve; an angle detecting device for detecting an angle between the photoelectric plate or solar energy collecting device and a horizontal line and sending a signal regarding information of the angle; and a controller for receiving and processing the signal from the angle detecting device for selectively proceeding with control of opening/closing, partially open extent, and a period of time of opening/closing or partially opening of the water filling control valve and the water discharge control valve.

The compression state of the elastic element can be changed by filling water into the water tank to adjust the angle facing the sun for maximum effect. Thus, the solar tracking device according to the preferred teachings of the present invention can be utilized on both sloping roofs and flat roofs of buildings.

Other objectives, advantages, and novel features of the invention will become more apparent from the following detailed description when taken in conjunction with the accompanying drawings.

### BRIEF DESCRIPTION OF THE DRAWINGS

FIG. 1 shows a schematic view of a solar tracking device according to the preferred teachings of the present invention used on a sloping roof.

FIG. 2 shows a schematic view of a solar tracking device according to the preferred teachings of the present invention used on a flat ground or a flat roof.

### DETAILED DESCRIPTION OF THE PREFERRED EMBODIMENTS

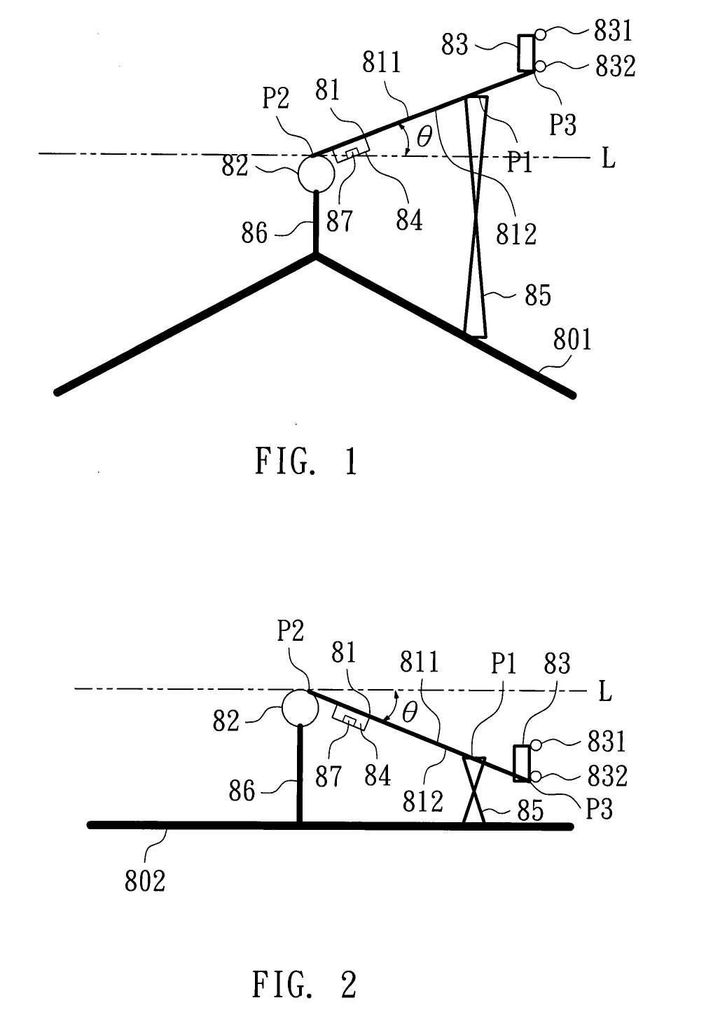

With reference to FIG. 1, an elastic compression type solar tracking device according to the preferred teachings of the present invention includes a photoelectric plate or solar energy collecting device 81 that is substantially plate-like and includes an irradiated side 811 and a shaded side 812. An elastic element 85 has an end abutting against the irradiated side 812 of the photoelectric plate or solar energy collecting device 81 to form a supporting point P1. The elastic element 85 may be an element allowing longitudinal elastic compression and preferably a spring. The elastic element 85 supports a point of the photoelectric plate or solar energy collecting device 81. Furthermore, the elastic element 85 and a post 86 together provide support for the photoelectric plate or solar energy collecting device 81. Nevertheless, the elastic element 85 can be compressed to different extends in response to different pressures and, thus, has a varying height in the vertical direction (the height of the elastic element 85 in the compressed state is different from that of the elastic element 85 in the restored state). Thus, the upper end of the elastic element 85 can be at different levels with reference to the post 86. Thus, the photoelectric plate or solar energy collecting device 81 can be located in a slanted state to change an angle between the irradiated side 811 of the photoelectric plate or solar energy collecting device 81 and a horizontal line L.

A rotational shaft 82 is coupled to the photoelectric plate or solar energy collecting device 81 at a supporting point P2 between the supporting point P1 where the elastic element 85 supports the photoelectric plate or solar energy collecting device 81 and an end edge of the photoelectric plate or solar energy collecting device 81, allowing the photoelectric plate or solar energy collecting device 81 to turn about the rotational shaft 82. Preferably, the rotational shaft 82 is located at the end edge of the photoelectric plate or solar energy collecting device 81.

The post 86 supports the rotational shaft 82 and, hence, the end edge of the photoelectric plate or solar energy collecting device 81. The post 86 is mounted on a ground, a flat roof of a building, or a sloping roof of a building. In the embodiment shown in FIG. 1, the post 86 is mounted on a top of a sloping roof 801. In the embodiment shown in FIG. 2, the post 86 is mounted on a flat roof 802.

A water tank 83 is mounted on the photoelectric plate or solar energy collecting device 81 in a location other than the supporting point P2 where the rotational shaft 82 supports the photoelectric plate or solar energy collecting device 81. Preferably, the water tank 83 is located at the other end edge P3 of the photoelectric plate or solar energy collecting device 81 opposite to the end edge P2 where the rotational shaft 82 supports the photoelectric plate or solar energy collecting device 81 to provide a long arm of force. Furthermore, the water tank 83 can be mounted on the irradiated side 811 or the shaded side 812 of the photoelectric plate or solar energy collecting device 81 as long as the water tank 83 can apply a downward force to the photoelectric plate or solar energy collecting device 81.

The water tank 83 includes a water filling control valve 831 and a water discharge control valve 832. Pipes are connected to the water filling control valve 831 and the water discharge control valve 832 for the purposes of filling or discharging water, wherein piping of which is omitted. When strong wind is coming, the water tank 83 can be filled with water to weight and, thus, retain the photoelectric plate or solar energy collecting device 81, avoiding the photoelectric plate or solar energy collecting device 81 from windlift.

An angle detecting device 84 is arranged to detect the angle between the photoelectric plate or solar energy collecting device 81 and the horizontal line L. A controller 87 is connected to the angle detecting device 84 for receiving and processing a signal regarding information of the angle from the angle detecting device 84. After processing, the controller 87 selectively proceeds with control of opening/closing, partially open extent, and a period of time of opening/closing or partially opening of the water filling control valve 831 and the water discharge control valve 832.

Operation of the solar tracking device according to the preferred teachings of the present invention will now be described. The water tank 83 is initially empty, and the water filling control valve 831 and the water discharge control valve 832 are closed. The elastic element 85 is in its extended state such that the photoelectric plate or solar energy collecting device 81 has a maximum angle with the horizontal line L. After “sunrise”, the water filling control valve 831 is opened to allow filling of water into the water tank 83. The controller 87 includes a timer connected to the water filling control valve 831 for controlling opening or partially open extent of the water filling control valve 831. The term “sunrise” used herein can be defined by the time preset by the timer in the controller 87. Alternatively, weather data including the trajectory of the sun, sunrise, and sunset of a given time and date as well as other weather data can be input into computer programs to obtain a predicated angle at any given time as the control parameters for controlling the water filling control valve 31 and/or the water discharge control valve 832.

The more the water is filled, the heavier the water tank 83 is and the more the elastic element 85 is compressed. As a result, the angle between the photoelectric plate or solar energy collecting device 81 and the horizontal line L becomes smaller.

The angle detecting device 84 may have various structures. Most importantly, the angle detecting device 84 is capable of detecting a change in the angle between the photoelectric plate or solar energy collecting device 81 and the horizontal line L and of sending a signal to the controller 87. In a case that the controller 87 detects that a certain angle is met within a preset period of time, the controller 87 closes the water filling control valve 831. Furthermore, when a preset period of time or a preset angle corresponding to the time or angle of sunset has passed, the controller 87 closes the water filling control valve 831. When the sun is below the horizon or a preset nighttime hour comes, the controller 87 opens the water discharge control valve 832 to empty the water tank 83 for tomorrow's use.

Although specific embodiments have been illustrated and described, numerous modifications and variations are still possible without departing from the teachings of the invention. The scope of the invention is limited by the accompanying claims.

1. A elastic compression type solar tracking device comprising:
a photoelectric plate or solar energy collecting device including an irradiated side and a shaded side;
an elastic element abutting against and supporting the irradiated side of the photoelectric plate or solar energy collecting device at a first supporting point;
a rotational shaft connected to and supporting the photoelectric plate or solar energy collecting device at a second supporting point between the first supporting point and an end edge of the photoelectric plate or solar energy collecting device;
a post for supporting the rotational shaft;
a water tank mounted on the photoelectric plate or solar energy collecting device in a location other than the second supporting point where the rotational shaft supports the photoelectric plate or solar energy collecting device, with the water tank including a water filling control valve and a water discharge control valve;
an angle detecting device for detecting an angle between the photoelectric plate or solar energy collecting device and a horizontal line and sending a signal regarding information of the angle; and
a controller for receiving and processing the signal from the angle detecting device for selectively proceeding with control of opening/closing, partially open extent, and a period of time of opening/closing or partially opening of the water filling control valve and the water discharge control valve.

2. The elastic compression type solar tracking device as claimed in claim 1 wherein the post is mounted on a ground, a sloping roof of a building or a flat roof of a building.

3. The elastic compression type solar tracking device as claimed in claim 1 wherein the water tank is mounted on the irradiated side of the photoelectric plate or solar energy collecting device.

4. The elastic compression type solar tracking device as claimed in claim 1 wherein the rotational shaft is mounted on the end edge of the photoelectric plate or solar energy collecting device.

5. The elastic compression type solar tracking device as claimed in claim 4 wherein the water tank is mounted on another end edge of the photoelectric plate or solar energy collecting device opposite to the end edge where the rotational shaft supports the photoelectric plate or solar energy collecting device to provide a long arm of force.

6. The elastic compression type solar tracking device as claimed in claim 1 wherein the elastic element is a spring.
